(19) United States
(12) Patent Application Publication
(10) Pub. No.: US 2024/0219837 A1
(43) Pub. Date: Jul. 4, 2024

(54) Substrate Processing Apparatus

(71) Applicant: Semes Co., Ltd, Cheonan-si (KR)

(72) Inventors: Ki Won HAN, Anseong-si (KR); Jun Ho SEO, Seoul (KR)

(73) Assignee: Semes Co., Ltd, Cheonan-si (KR)

(21) Appl. No.: 18/396,996

(22) Filed: Dec. 27, 2023

(30) Foreign Application Priority Data
Dec. 29, 2022 (KR) 10-2022-0189546
Apr. 3, 2023 (KR) 10-2023-0043596

(51) Int. Cl. G03F 7/16

(52) U.S. Cl. CPC G03F 7/16

(57) ABSTRACT

Provided is a substrate processing apparatus which effectively exhausts organic gas, such as ammonia, generated in the process of processing a substrate by using gas. The substrate processing apparatus includes: a housing provided with a processing space in which a substrate is processed therein; a hand which transfers the substrate to the processing space; a guide located at a side portion of the housing, and which guides a vertical movement of the hand; and an exhaust duct located adjacent to the housing and the guide, and which provides an exhaust path of the processing space, and an exhaust path of an interior space of the guide.

### CROSS-REFERENCE TO RELATED APPLICATIONS

This application claims priority to and the benefit of Korean Patent Application Nos. 10-2022-0189546 and 10-2023-0043596 filed in the Korean Intellectual Property Office on Dec. 29, 2022 and Apr. 3, 2023 the entire contents of which are incorporated herein by reference.

### TECHNICAL FIELD

The present invention relates to a substrate processing apparatus.

### BACKGROUND ART

A hydrophobization treatment process is a process that changes a surface of a substrate from hydrophilic to hydrophobic by supplying hydrophobizing gas to the substrate before the photoresist application process so that the photoresist is applied thinly and uniformly on the substrate. An example of the hydrophobizing gas is HMDS (Hexamethyldisilazane) gas, and the process of hydrophobizing the surface of the substrate by using HMDS gas produces ammonia gas that causes odor.

Referring to Korean Patent Application Laid-Open No. 10-2020-0019750 (published on Feb. 24, 2020), some substrate processing apparatuses include a hydrophobization treating chamber (described as an “AHP unit” in the publication) that performs a hydrophobization treatment process.

Meanwhile, a transfer unit is provided in the vicinity of the hydrophobization treating chamber which transfers the substrate to the processing space of the hydrophobization treating chamber, and in the process of transferring the substrate that has completed the hydrophobization treatment by the transfer unit, there is a problem that some of the ammonia gas is not properly exhausted and diffuses to the periphery of the hydrophobization treating chamber.

### SUMMARY OF THE INVENTION

The present invention has been made in an effort to provide a substrate processing apparatus which effectively exhausts organic gas, such as ammonia, generated in the process of processing a substrate by using gas.

The object of the present invention is not limited thereto, and other objects not mentioned will be clearly understood by those of ordinary skill in the art from the following description.

An exemplary embodiment of the present invention provides a substrate processing apparatus including: a housing provided with a processing space in which a substrate is processed therein; a hand which transfers the substrate to the processing space; a guide located at a side portion of the housing, and for guiding a vertical movement of the hand; and an exhaust duct located adjacent to the housing and the guide, and which provides an exhaust path of the processing space, and an exhaust path of an interior space of the guide.

In some embodiments, the substrate processing apparatus may further include: a heating unit provided in the processing space and which heats the substrate; and a gas supply unit which supplies processing gas to the processing space.

In some embodiments, the housing may be provided with a first exhaust port connected with an interior space of the exhaust duct, and one of the housing and the exhaust duct may be provided with a shutter for opening and closing the first exhaust port.

In some embodiments, the shutter may be provided to be adjustable an opening rate of the first exhaust port.

In some embodiments, a side portion of the housing opposite to a side portion provided with the hand among the side portions of the housing may be provided with a second exhaust port which exhausts an internal fluid of the processing space to the outside.

In some embodiments, the exhaust duct may be provided with an intake fan.

In some embodiments, the processing gas may include hexamethyldisilane (HMDS).

In some embodiments, the shutter may be provided to be opened immediately before the heating unit is opened and to be closed immediately before the heating unit is closed.

In some embodiments, the guide and the exhaust duct may be integrally provided.

Another exemplary embodiment of the present invention provides a substrate processing apparatus including: a heat treating chamber which performs a heat treatment on a substrate; and a transfer unit which loads and unloads the substrate to or from the heat treating chamber, in which the heat treating chamber includes: a housing provided with a processing space in which the substrate is processed therein; a heating unit provided in the processing space and which heats the substrate; and a gas supply unit which supplies processing gas to the processing space, and the transfer unit includes: a hand which transfers the substrate to the processing space; a guide located at a side portion of the housing and which guides a vertical movement of the hand; and an exhaust duct located adjacent to the housing and the guide, and which provides an exhaust path of the processing space, and an exhaust path for an interior space of the guide.

The substrate processing apparatus according to the embodiment effectively exhausts organic gas, such as ammonia, generated in the process of processing the substrate by using gas.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a perspective view schematically illustrating a substrate processing apparatus according to an exemplary embodiment of the present invention.

FIG. 2 is a cross-sectional view of the substrate processing apparatus illustrating an applying block or a developing block of FIG. 1.

FIG. 3 is a top plan view of the substrate processing apparatus of FIG. 1.

FIG. 4 is a diagram illustrating an example of a hand of a transfer robot of FIG. 3.

FIG. 5 is a planar cross-sectional view schematically illustrating one example of a heat treating chamber of FIG. 3.

FIG. 6 is a front cross-sectional view of the heat treating chamber of FIG. 5.

FIG. 7 is a perspective view illustrating a hydrophobization treating chamber and a transfer unit.

FIG. 8 is a top plan view of the hydrophobization treating chamber of FIG. 7.

FIG. 9 is a diagram illustrating a gas flow path in a peripheral region of the hydrophobization treating chamber of FIG. 8.

Various features and advantages of the non-limiting embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

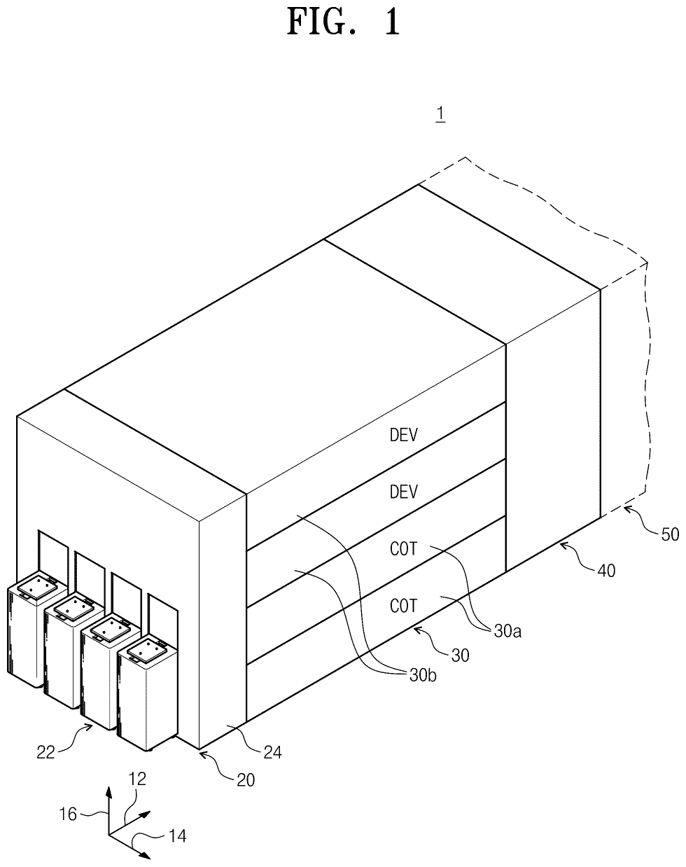

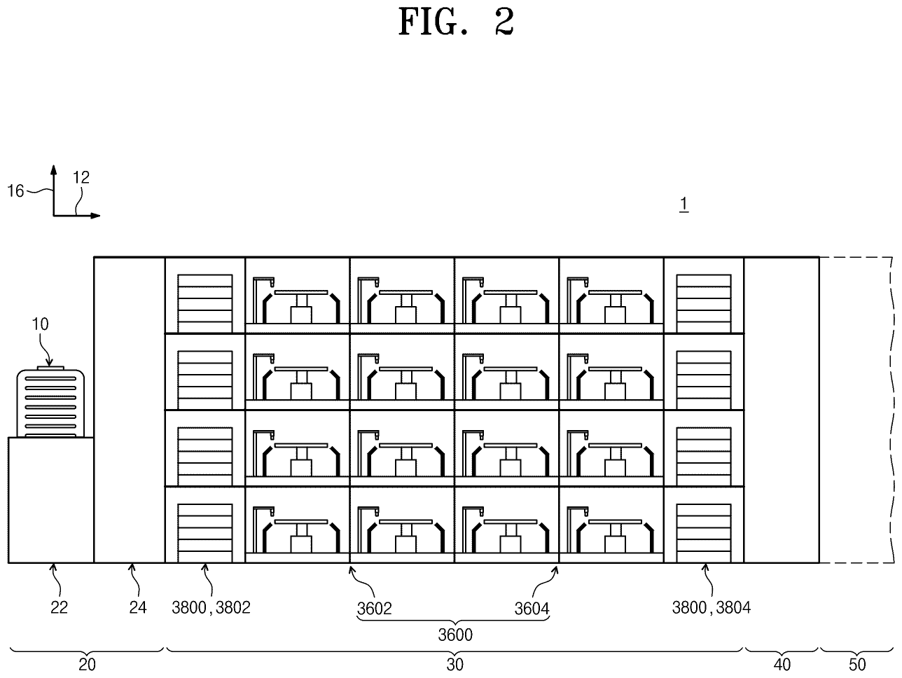

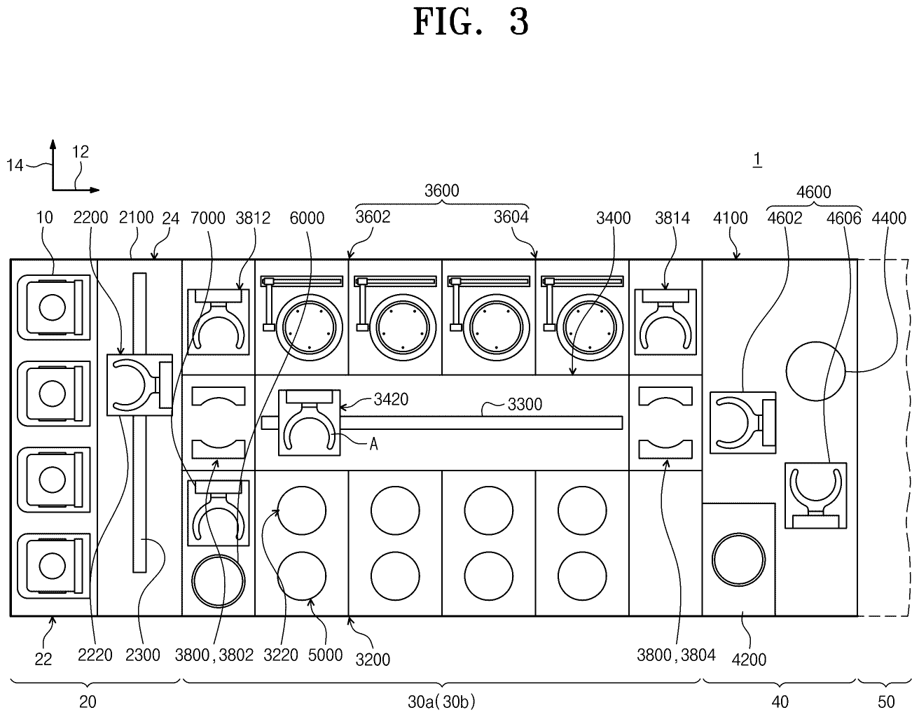

FIG. 1 is a perspective view schematically illustrating a substrate processing apparatus according to an exemplary embodiment of the present invention, FIG. 2 is a cross-sectional view of the substrate processing apparatus illustrating an applying block or a developing block of FIG. 1, and FIG. 3 is a top plan view of the substrate processing apparatus of FIG. 1.

Referring to FIGS. 1 to 3, a substrate processing apparatus 1 includes an index module 20, a treating module 30, and an interface module 40. According to the exemplary embodiment, the index module 20, the treating module 30, and the interface module 40 may be sequentially arranged in series. Hereinafter, a direction in which the index module 20, the treating module 30, and the interface module 40 are arranged is referred to as an X-axis direction 12, a direction perpendicular to the X-axis direction 12 when viewed from above is referred to as a Y-axis direction 14, and a direction perpendicular to both the X-axis direction 12 and the Y-axis direction 14 is referred to as a Z-axis direction 16.

The index module 20 transfers a substrate W from a vessel 10 in which the substrate W is accommodated to the treating module 30, and accommodates the substrate W of which the treatment is completed in the vessel 10. The longitudinal direction of the index module 20 is provided in the Y-axis direction 14. The index module includes a load port 22 and an index frame 24. Based on the index frame 24, the load port 22 is located at a side opposite to the treating module 30. The vessels 10 in which the substrates W are accommodated are placed on the load port 22. A plurality of load ports 22 may be provided, and the plurality of load ports 22 may be disposed along the Y-axis direction 14.

As the vessel 10, an airtight vessel 10, such as a Front Open Unified Pod (FOUP), may be used. The vessel 10 may be placed on the load port 22 by a transfer means (not illustrated), such as an overhead transfer, an overhead conveyor, or an automatic guided vehicle, or an operator.

An index robot 2200 is provided inside the index frame 24. Within the index frame 24, a guide rail 2300 is provided with a longitudinal direction in the Y-axis direction 14, and the index robot 2200 may be movably provided on the guide rail 2300. The index robot 2200 includes a hand 2220 on which the substrate W is placed, and the hand 2220 may be provided to be movable forward and backward, rotatable about the Z-axis direction 16, and movable along the Z-axis direction 16.

The treating module 30 performs an application process and a developing process on the substrate W. The treating module 30 includes an applying block 30a and a developing block 30b. The applying block 30a performs an application process on the substrate W, and the developing block 30b performs a developing process on the substrate W. A plurality of applying blocks 30a is provided, and is provided to be stacked on each other. A plurality of developing blocks 30b is provided, and the developing blocks 30b is provided to be stacked on each other. According to the exemplary embodiment of FIG. 3, two applying blocks 30a are provided, and two developing blocks 30b are provided. The applying blocks 30a may be disposed under the developing blocks 30b. According to an exemplary embodiment, two applying blocks 30a may perform the same process and may be provided in the same structure. Further, the two developing blocks 30b may perform the same process and may be provided in the same structure.

Referring to FIG. 3, the applying block 30a includes a heat treating chamber 3200, a transfer chamber 3400, a liquid treating chamber 3600, and a buffer chamber 3800. The heat treating chamber 3200 performs a heat treating process on the substrate W. The heat treating process may include a cooling process and a heating process. The liquid treating chamber 3600 forms a liquid film by supplying a liquid onto the substrate. The liquid film may be a photoresist film or an anti-reflective film. The transfer chamber 3400 transfers the substrate W between the heat treating chamber 3200 and the liquid treating chamber 3600 within the applying block 30a.

The transfer chamber 3400 is provided with a longitudinal direction parallel to the X-axis direction 12. A transfer robot 3420 is provided to the transfer chamber 3420. The transfer robot 3420 transfers the substrate between the heat treating chamber 3200, the liquid treating chamber 3600, and the buffer chamber 3800. According to the example, the transfer robot 3420 includes a hand A on which the substrate W is placed, and the hand A may be provided to be movable forward and backward, rotatable about the Z-axis direction 16, and movable along the Z-axis direction 16. A guide rail 3300 of which a longitudinal direction is provided to be parallel to the X-axis direction X is provided in the transfer chamber 3400, and the transfer robot 3420 may be provided to be movable on the guide rail 3300.

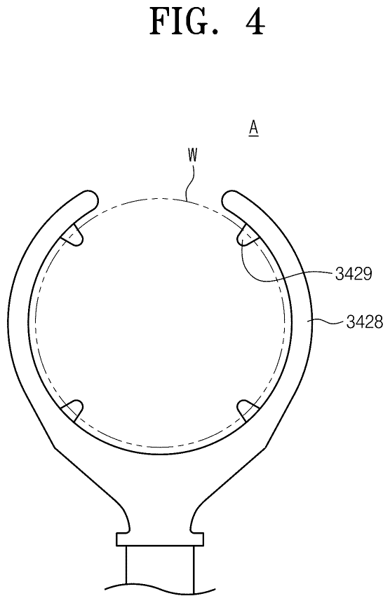

FIG. 4 is a diagram illustrating an example of the hand of the transfer robot of FIG. 3. Referring to FIG. 4, the hand A includes a base 3428 and a support protrusion 3429. The base 3428 may have an annular ring shape in which a portion of the circumference is bent. The base 3428 has an inner diameter larger than a diameter of the substrate W. The support protrusion 3429 extends inwardly therefrom from the base 3428. A plurality of support protrusions 3428 is provided, and supports an edge region of the substrate W. In one example, four support protrusions 3429 may be provided at the same interval.

Referring again to FIGS. 2 and 3, the heat treating chamber 3200 is provided in plurality. The heat treating chambers 3200 are arranged in a row along the X-axis direction 12. The heat treating chambers 3200 are positioned at one side of the transfer chamber 3400.

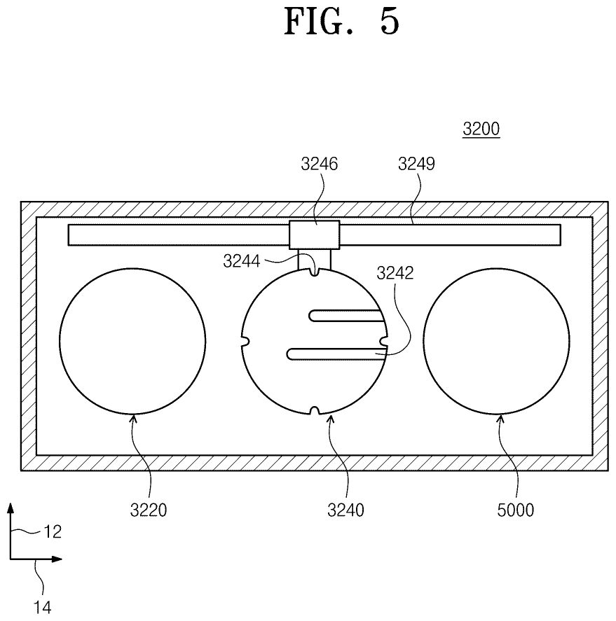

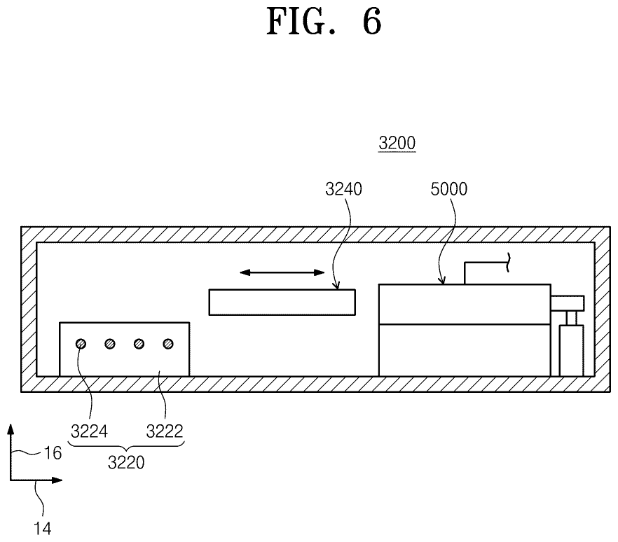

FIG. 5 is a planar cross-sectional view schematically illustrating one example of the heat treating chamber of FIG. 3, and FIG. 6 is a front cross-sectional view of the heat treating chamber of FIG. 5. The heat treating chamber 3200 includes a housing 3210, a cooling unit 3220, a heating unit 5000, and a transfer plate 3240.

The housing 3210 is provided in the shape of a generally rectangular parallelepiped. An inlet (not illustrated) through which the substrate W enters and exits is formed on a lateral wall of the housing 3210. The inlet may remain open. Optionally, a door (not illustrated) may be provided to open and close the inlet. The cooling unit 3220, the heating unit 5000, and the transfer plate 3240 are provided within the housing 3210. The cooling unit 3220 and the heating unit 5000 are provided side-by-side along the Y-axis direction 14. According to the example, the cooling unit 3220 may be located closer to the transfer chamber 3400 than the heating unit 5000.

The cooling unit 3220 includes a cooling plate 3222. The cooling plate 3222 may have a generally circular shape when viewed from the top. A cooling member 3224 is provided to the cooling plate 3222. According to the example, the cooling member 3224 is formed inside the cooling plate 3222 and may be provided as a flow path through which the cooling fluid flows.

The transfer plate 3240 is provided in a substantially disk shape, and has a diameter corresponding to that of the substrate W. A notch 3244 is formed at the edge of the transfer plate 3240. The notch 3244 may have a shape that corresponds to the protrusion 3429 formed on the hand A of the transfer robot 3420 described above. Further, the notches 3244 are provided in a number corresponding to the number of protrusions 3429 formed on the hand A, and are formed in locations corresponding to the protrusions 3429. When vertical positions of the hand A and the transfer plate 3240 are changed from a position where the hand A and the transfer plate 3240 are aligned in the vertical direction, the substrate W is transferred between the hand A and the transfer plate 3240. The transfer plate 3240 is mounted on the guide rail 3249 and is moved along the guide rails 3249 by a driver 3246. A plurality of slit-shaped guide grooves 3242 is provided in the transfer plate 3240. The guide groove 3242 extends from the end of transfer plate 3240 to the interior of transfer plate 3240. The guide groove 3242 is provided with a longitudinal direction along the Y-axis direction 14, and the guide grooves 3242 are spaced apart from each other along the X-axis direction 12. The guide groove 3242 prevents the transfer plate 3240 and the lift pin from interfering with each other when a handover of the substrate W is made between the transfer plate 3240 and the heating unit 5000.

Referring back to FIGS. 2 and 3, a plurality of buffer chambers 3800 is provided. Some of the buffer chambers 3800 are disposed between the index module 20 and the carrying chamber 3400. Hereinafter, the foregoing buffer chambers are referred to as front buffers 3802. A plurality of front buffers 3802 is provided, and is positioned to be stacked on each other in the vertical direction. Another portion of the buffer chambers 3802 and 3804 is disposed between the transfer chamber 3400 and the interface module 40. Hereinafter, the foregoing buffer chambers are referred to as rear buffers 3804. A plurality of rear buffers 3804 is provided, and is positioned to be stacked on each other in the vertical direction. The front buffers 3802 and the rear buffers 3804 temporarily store the plurality of substrates W, respectively. The substrate W stored in the front buffer 3802 is loaded or unloaded by the index robot 2200 and the carrying robot 3420. The substrate W stored in the rear buffer 3804 is loaded or unloaded by the transfer robot 3420 and the first robot 4602.

The developing block 30b includes a heat treating chamber 3200, a transfer chamber 3400, and a liquid treating chamber 3600. The heat treating chamber 3200, the transfer chamber 3400, and the liquid treating chamber 3600 of the developing block 30b are provided in a structure and arrangement that is substantially similar to the heat treating chamber 3200, the transfer chamber 3400, and the liquid treating chamber 3600 of the applying block 30a, so that descriptions thereof will be omitted. Only, in the developing block 30b, the liquid treating chambers 3600 are all provided as the developing chambers 3600 which supply developers and develop the substrate.

The interface module 40 connects the treating module 30 to an external exposing device 50. The interface module 40 includes an interface frame 4100, an additional process chamber 4200, an interface buffer 4400, and a transfer member 4600.

A fan filter unit for forming a descending airflow therein may be provided at an upper end of the interface frame 4100. The additional process chamber 4200, the interface buffer 4400, and the transfer member 4600 are disposed inside the interface frame 4100. The additional process chamber 4200 may perform a predetermined additional process before the substrate W, which has been completely treated in the applying block 30a, is loaded into the exposing device 50. Optionally, the additional process chamber 420 may perform a predetermined additional process before the substrate W, which has been completely processed in the exposing device 50, is loaded into the developing block 30b. According to one example, the additional process may be an edge exposure process of exposing an edge region of the substrate W, a top surface cleaning process of cleaning the top surface of the substrate W, or a lower surface cleaning process of cleaning the lower surface of the substrate W. A plurality of additional process chambers 4200 is provided, and may be provided to be stacked on each other. All of the additional process chambers 4200 may be provided to perform the same process. Optionally, a part of the additional process chambers 4200 may be provided to perform different processes.

The interface buffer 4400 provides a space in which the substrate W transferred between the applying block 30a, the additional process chamber 4200, the exposing device 50, and the developing block 30b is temporarily stayed during the transfer. A plurality of interface buffers 4400 is provided, and the plurality of interface buffers 4400 may be provided to be stacked on each other.

According to one example, based on the longitudinal extension line of the transfer chamber 3400, the additional process chamber 4200 may be disposed on one side, and the interface buffer 4400 may be disposed on the other side.

The transfer member 4600 provides the substrate W between the applying block 30a, the additional process chamber 4200, the exposing device 50, and the developing block 30b. The transfer member 4600 may be provided as one or a plurality of robots. In one example, the transfer member 4600 includes a first robot 4602 and a second robot 4606. The first robot 4602 may be provided to transfer the substrate W between the applying block 30a, the additional process chamber 4200, and the interface buffer 4400, the interface robot 4606 may be provided to transfer the substrate W between the interface buffer 4400 and the exposing device 50, and the second robot 4604 may be provided to transfer the substrate W between the interface buffer 4400 and the developing block 30b.

The first robot 4602 and the second robot 4606 each include a hand on which the substrate W is placed, and the hand may be provided to be movable forward and backward, rotatable about an axis parallel to the Z-axis direction 16, and movable along the Z-axis direction 16.

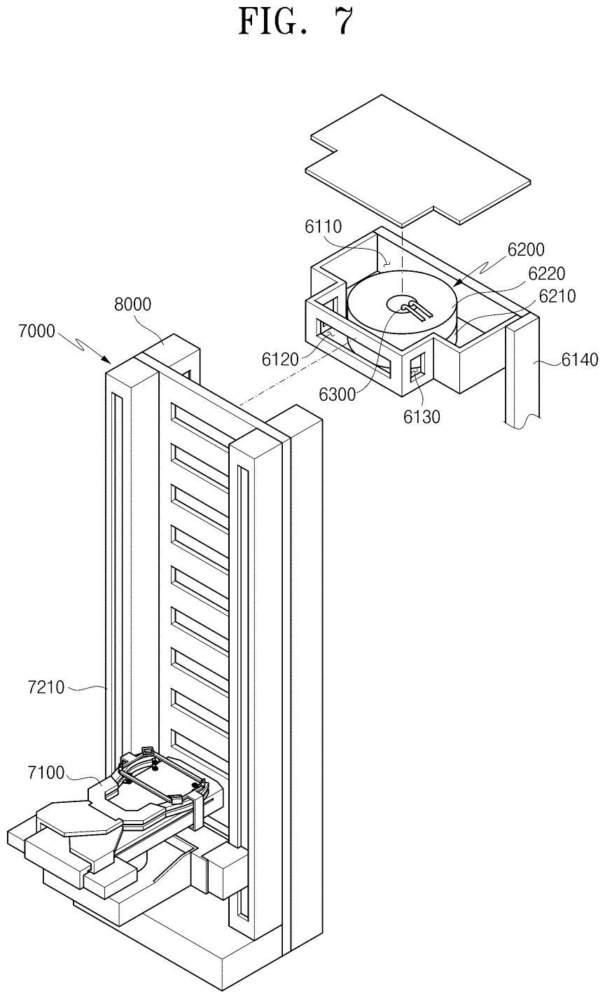

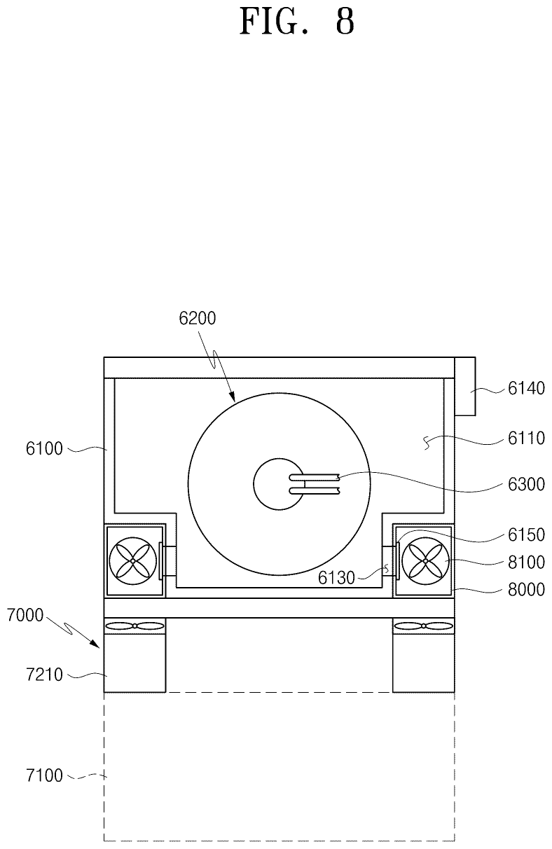

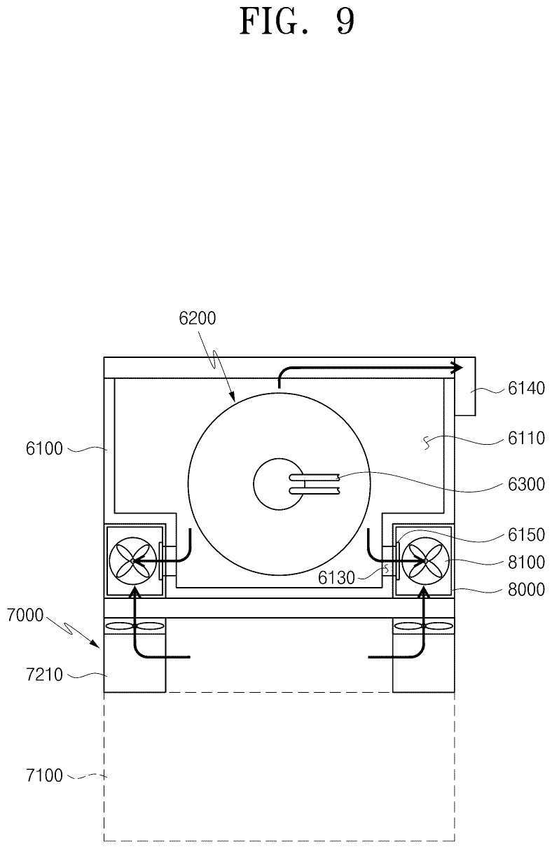

FIG. 7 is a perspective view illustrating a hydrophobization treating chamber and the transfer unit, FIG. 8 is a top plan view of the hydrophobization treating chamber of FIG. 7, and FIG. 9 is a diagram illustrating a gas flow path in a peripheral region of the hydrophobization treating chamber of FIG. 8.

Referring to FIGS. 3, 7, and 9, the substrate processing apparatus 1 further includes a hydrophobization treating chamber 6000, a transfer unit 7000, and an exhaust duct 8000.

The hydrophobization treating chamber 6000 performs hydrophobization treatment on the substrate W, and the transfer unit 7000 transfers the substrate W to the hydrophobization treating chamber 6000. A hydrophobization treatment refers to a treatment that changes a surface of the substrate W from hydrophilic to hydrophobic by supplying hydrophobizing gas to the substrate W before the photoresist application process so that the photoresist is applied thinly and uniformly on the substrate W. The hydrophobization gas may be Hexamethyldisilane (HMDS) gas.

In some embodiments, the hydrophobization treating chamber 6000, the transfer unit 7000, and the buffer chamber 3800 may be arranged sequentially along the Y-axis direction 14. The buffer chamber 3800 may be the front buffer 3802, and the transfer unit 7000 may be provided to transfer the substrate W between the front buffer 3802 and the hydrophobization treating chamber 6000.

A plurality of hydrophobization treating chambers 6000 may be provided, and the plurality of hydrophobization treating chambers 6000 may be arranged along the z-axis direction 16.

The hydrophobization treating chamber 6000 may include a housing 6100, a heating unit 6200, and a gas supply unit 6300.

The housing 6100 may be provided in a shape that is substantially cuboidal. An interior of the housing 6100 is provided with a processing space 6110 where the substrate W is processed. A front surface of the housing 6100 is provided with a substrate entrance port 6120 that provides an entry and exit path for the substrate W. The substrate entrance port 6120 may be further provided with a door (not illustrated).

The heating unit 6200 is provided in the processing space 6110, and heats the substrate W.

The heating unit 6200 may include a lower body 6210 fixedly mounted to the bottom of the housing 6100, and an upper body 6220 provided on top of the lower body 6210 and configured to be operable in an up and down direction by a driver (not illustrated). The lower body 6210 and the upper body 6220 are not limited to a particular shape. As one example, the lower body 6210 and the upper body 6220 may be provided in a cylindrical shape. A boundary between the lower body 6210 and the upper body 6220 may be provided with a space in which the substrate W to be heated is seated.

The gas supply unit 6300 supplies gas to the processing space 6110. A gas supply source (not illustrated) of the gas supply unit 6300 may be located outside of the housing 6100. The gas provided by the gas supply unit 6300 may be hydrophobization gas, such as hexamethyldisilane (HMDS). A portion of the gas supply unit 6300 may be located on the top surface of the upper body 6220, and may be configured to supply gas to the boundary between the lower body 6210 and the upper body 6220. The boundary may be the space where the substrate W is seated.

When the substrate W is heated by the heating unit 6200 and hydrophobization gas is supplied to the boundary between the lower body 6210 and the upper body 6220 on which the substrate W is located, the surface of the substrate W changes from hydrophilic to hydrophobic. Next, when the upper body 6220 is raised by the driver, organic gas, such as ammonia gas, generated during the hydrophobization process may diffuse from the heating unit 6200 into the interior of the housing 6100.

The transfer unit 7000 may be provided at a front portion of the hydrophobization treating chamber 6000. The transfer unit 7000 may include a hand 7100 and a guide 7200.

The hand 7100 transfers the substrate W to the processing space 6110. The hand 7100 is not limited to any particular shape. The hand 7100 may be provided to be axially rotatable about the z-axis direction 16 and adjustable in length in the xy-plane.

The guide 7200 is disposed along the z-axis direction 16 and guides the vertical movement of the hand 7100. The guide 7200 may include a pair of columnar portions 7210 spaced apart by a length corresponding to the width of the housing 6100. The interior of the columnar portion 7210 may be provided with space for fluid to move through. In some embodiments, the guide 7200 may be provided with at least one or more ventilation holes (not illustrated) to allow gases or particles in the vicinity of the guide 7200 to move into the interior of the guide 7200.

The exhaust duct 8000 is positioned adjacent to the housing 6100 and the guide 7200 and provides an exhaust path for the processing space 6110 and an exhaust path for the space inside the guide 7200. In one example, the exhaust duct 8000 may be provided between a front surface of the housing 6100 and a back surface of the guide 7200.

The interior of the exhaust duct 800 may be provided with at least one intake fan 8100. The intake fan 8100 sucks gas from the processing space 6110 and gas from the space inside the guide 7200 into the exhaust duct 800.

The housing 6100 may be provided with a first exhaust port 6130 that is in connection with the exhaust duct 8000 on one side. The number of first exhaust ports 6130 provided in one housing 6100 is not limited. At least one of the housing 6100 and the exhaust duct 8000 may be provided with a shutter 6150 to open and close the first exhaust port 6130.

The opening rate of the shutter 6150 may be automatically adjustable by a controller (not illustrated). The shutter 6150 may be controlled by the controller to open immediately before the heating unit 6200 is opened and organic gas is diffused into the processing space 6110. The shutter 6150 may be controlled by the controller to close just before the heating unit 6200 is closed and the hydrophobization treatment of the substrate W is performed. A state in which the heating unit 6200 is closed may be defined as a state in which the lower body 6210 is lowered by the driver and the upper body 6220 is in close contact.

At the boundary of the guide 7200 and the exhaust duct 800, a connection hole connecting the interior space of the guide 7200 and the interior space of the exhaust duct 800 may be provided. In some embodiments, the guide 7200 and the exhaust duct 800 may be integrally provided.

On the side of the housing 6100 opposite the side on which the hand 7100 is provided, among the sides of the housing 6100, a second exhaust port 6140 to exhaust internal fluids of the processing space 6110 to the outside may be provided. In some embodiments, a first exhaust port 6130 may be provided at a front portion of the housing 6100 and a second exhaust port 6140 may be provided at a rear portion of the housing 6100 to allow for bi-directional exhaust of the housing 6100.

In some embodiments, a plurality of housings 6100 including first exhaust ports 6130 and the shutters 6150 may be provided and arranged along the height direction of guide 7200. In this case, the shutters 6150 matched to the housings 6100 may each be provided to be independently drivable. For example, as the process progresses, some of the shutters 6150 may be controlled by the controller to have different opening rates. If substrate processing is completed in the plurality of housings 6100 at the same time, the shutters 6150 may be controlled to have lower opening rates in the order of the housings 6100 closest in distance to the intake fan 8100, thereby calibrating the exhaust volume of each of the housings 6100 to achieve uniform exhaust from the housings 6100.

In some embodiments, some of the heat treating chambers 3200 may be provided to replace the function of the hydrophobization treating chamber 6000 described above. For example, the heat treating chambers 3200 may include the previously described housing, heating unit, gas supply unit, and the like, and the transfer robot 3420 may replace the functions of the transfer unit 7000. In addition, a separate exhaust duct is provided between the heat treating chamber 3200, which performs the hydrophobization treatment, and the transfer robot 3420, which transfers the substrate W to the heat treating chamber 3200.

The aforementioned substrate processing apparatus 1 is configured so that organic gas, such as ammonia, generated in the process of processing the substrate W by using gas is exhausted through the exhaust duct 8000 located in the vicinity of the transfer unit 7000, thereby essentially preventing the organic gas from spreading to the periphery of the housing 6100 through the transfer unit 7000.

It should be understood that exemplary embodiments are disclosed herein and that other variations may be possible. Individual elements or features of a particular embodiment are not generally limited to the particular embodiment, but are interchangeable and may be used in selected embodiments, where applicable, even if not specifically illustrated or described. The modifications are not to be considered as departing from the spirit and scope of the invention, and all such modifications that would be obvious to one of ordinary skill in the art are intended to be included within the scope of the accompanying claims.

What is claimed is:

1. A substrate processing apparatus comprising:
a housing provided with a processing space in which a substrate is processed therein;
a hand which transfers the substrate to the processing space;
a guide located at a side portion of the housing, and for guiding a vertical movement of the hand; and
an exhaust duct located adjacent to the housing and the guide, and which provides an exhaust path of the processing space, and an exhaust path of an interior space of the guide.

2. The substrate processing apparatus of claim 1, wherein the housing is provided with a first exhaust port connected with an interior space of the exhaust duct, and
any one of the housing and the exhaust duct is provided with a shutter for opening and closing the first exhaust port.

3. The substrate processing apparatus of claim 2, wherein the shutter is provided to be adjustable an opening rate of the first exhaust port.

4. The substrate processing apparatus of claim 2, wherein a side portion of the housing opposite to a side portion provided with the hand among the side portions of the housing is provided with a second exhaust port which exhausts an internal fluid of the processing space to the outside.

5. The substrate processing apparatus of claim 1, wherein the exhaust duct is provided with an intake fan.

6. The substrate processing apparatus of claim 1, further comprising:
a heating unit provided in the processing space and which heats the substrate; and
a gas supply unit which supplies processing gas to the processing space.

7. The substrate processing apparatus of claim 6, wherein the processing gas includes hexamethyldisilane (HMDS).

8. The substrate processing apparatus of claim 6, wherein the shutter is provided to be opened immediately before the heating unit is opened.

9. The substrate processing apparatus of claim 6, wherein the shutter is provided to be closed immediately before the heating unit is closed.

10. The substrate processing apparatus of claim 1, wherein the guide and the exhaust duct are integrally provided.

11. The substrate processing apparatus of claim 1, wherein the housing is provided in a plurality, and arranged along a height direction of the guide,
each of the housings is provided with a first exhaust port connected with an interior space of the exhaust duct, and a shutter for opening and closing the first exhaust port, and
the shutters matched to the housings are each provided to be independently operable.

12. The substrate processing apparatus of claim 8, further comprising:
a controller which controls the shutters,
the controller causes some of the shutters to have different opening rates during the process.

13. A substrate processing apparatus comprising:
a heat treating chamber which performs a heat treatment on a substrate; and
a transfer unit which loads or unloads the substrate to or from the heat treating chamber,
wherein the heat treating chamber includes:
a housing provided with a processing space in which the substrate is processed therein;
a heating unit provided in the processing space and which heats the substrate; and
a gas supply unit which supplies processing gas to the processing space, and
the transfer unit includes:
a hand which transfers the substrate to the processing space;
a guide located at a side portion of the housing and which guides a vertical movement of the hand; and
an exhaust duct located adjacent to the housing and the guide, and which provides an exhaust path of the processing space, and an exhaust path for an interior space of the guide.

14. The substrate processing apparatus of claim 13, wherein the housing is provided with a first exhaust port connected with an interior space of the exhaust duct, and
any one of the housing and the exhaust duct is provided with a shutter for opening and closing the first exhaust port.

15. The substrate processing apparatus of claim 14, wherein the shutter is provided to be adjustable an opening rate of the first exhaust port.

16. The substrate processing apparatus of claim 13, wherein the exhaust duct is provided with an intake fan.

17. The substrate processing apparatus of claim 13, wherein the processing gas includes hexamethyldisilane (HMDS).

18. A substrate processing apparatus comprising:
an index module including a load port in which a container accommodating a substrate is seated;
a processing module which receives the substrate accommodated in the container and performs a substrate processing process;
a heat treating chamber which performs a heat treatment on the substrate; and
a liquid treating chamber which performs a liquid treatment on the substrate;
a transfer chamber disposed between the heat treating chamber and the liquid treating chamber;
a buffer chamber disposed between the index module and the transfer chamber;
a hydrophobization treating chamber which performs a hydrophobization treatment on the substrate; and
a transfer unit which transfers the substrate between the buffer chamber and the hydrophobization treating chamber,
wherein the index module and the processing module are arranged in a first direction,
the hydrophobization treating chamber, the transfer unit, and the buffer chamber are sequentially arranged along a second direction,
the second direction is perpendicular to the first direction when viewed from above,
the hydrophobization treating chamber includes:
a housing provided with a processing space in which the substrate is processed therein;
a heating unit provided in the processing space and which heats the substrate; and
a gas supply unit which supplies processing gas to the processing space, and
the transfer unit includes:
a hand which transfers the substrate to the processing space;
a guide located at a side portion of the housing and which guides a vertical movement of the hand; and
an exhaust duct located adjacent to the housing and the guide, and which provides an exhaust path of the processing space, and an exhaust path of an interior space of the guide.

19. The substrate processing apparatus of claim 18, wherein the housing is provided with a first exhaust port connected with an interior space of the exhaust duct, and
any one of the housing and the exhaust duct is provided with a shutter for opening and closing the first exhaust port.

20. The substrate processing apparatus of claim 18, wherein the processing gas includes hexamethyldisilane (HMDS).
